(19) United States
(12) Patent Application Publication
(10) Pub. No.: US 2026/0343932 A1
(43) Pub. Date: Oct. 29, 2026

(54) FET MICROELECTRONIC DEVICE COMPRISING LARGE CONTACT SURFACES BETWEEN THE CONDUCTION CHANNEL AND THE SOURCE AND DRAIN REGIONS

(71) Applicant: COMMISSARIAT À L'ÉNERGIE ATOMIQUE ET AUX ÉNERGIES ALTERNATIVES, Paris (FR)

(72) Inventors: Sylvain BARRAUD, Grenoble Cedex 09 (FR); Rémi COQUAND, Grenoble Cedex 09 (FR); Shay REBOH, Grenoble Cedex 09 (FR)

(73) Assignee: COMMISSARIAT À L'ÉNERGIE ATOMIQUE ET AUX ÉNERGIES ALTERNATIVES, Paris (FR)

(21) Appl. No.: 19/139,105

(22) PCT Filed: Dec. 22, 2023
(86) PCT No.: PCT/FR2023/052106

§ 371 Date: Jun. 13, 2025

(30) Foreign Application Priority Data
Dec. 22, 2022 (FR) FR2214259

(51) Int. Cl. H10D 30/47; H10D 30/01

(52) U.S. Cl. CPC H10D 30/481; H10D 30/017

(57) ABSTRACT

An FET microelectronic device including a semiconductor layer, a first area of which forms a channel; several gates and a gate dielectric layer arranged on the first area, the gates being separate and spaced apart from one another; dielectric spacers arranged against sidewalls of the gates; source/drain regions electrically coupled to the first area via second areas of the active layer extending between the source/drain regions and the dielectric spacers, wherein the second areas form a continuous layer with the first area.

### TECHNICAL FIELD

The invention relates to the field of microelectronic devices applied to advanced CMOS technologies. In particular, the invention covers FET (“Field-Effect Transistor”) microelectronic devices, in particular RFET (“Reconfigurable Field-Effect Transistor”) microelectronic devices, in particular based on two-dimensional materials, or 2D materials, or semiconductor oxides, as well as the production of such microelectronic devices.

### PRIOR ART

Electronics miniaturization is constantly on the rise, but the industry is now approaching the scale limit for conventional materials such as silicon. Recently, 2D materials have emerged as promising candidates for use in miniature electronic and optoelectronic devices because of their unique properties and the very thin layers of these materials, which can be made up of a single layer of atoms or molecules.

The document by K. P. O'Brien et al., “Advancing 2D Monolayer CMOS Through Contact, Channel and Interface Engineering,” 2021 IEEE International Electron Devices Meeting (IEDM), 2021, pp. 7.1.1-7.1.4, suggests making a MOSFET transistor by integrating an MoS₂ layer to form the conduction channel. This layer is connected to two metallic source and drain regions made of gold, palladium, TiN, tungsten or nickel. The rear gate is formed by a doped silicon layer positioned at the rear face beneath a dielectric layer made of SiO₂, HfO₂ or Al₂O₃.

In order to overcome the constraints related to the deposition of the metallic materials of the source and drain regions on the 2D material, it is possible to form these regions not on the upper face of the 2D material layer, but against the sidewalls of the 2D material layer. Nonetheless, this configuration, so-called “side contact”, is problematic because the contact surface between the 2D material layer and the source and drain regions is small, which creates considerable contact resistance at the interfaces between the 2D material layer and the source and drain regions.

The document US 2022/045176 A1 describes several methods for making “gate-last” type FET transistors, wherein silicon portions serve as a support for the deposition of a 2D material layer. In addition to the disadvantages associated with the fact that the transistors produced have “side contact” type channel/source-drain interfaces, the silicon portions used to deposit the 2D material form a potential barrier at the interface with the 2D material, which is not desirable because part of the charge transport can take place in these silicon portions and not in the 2D material.

### DISCLOSURE OF THE INVENTION

One object of the present invention is to propose an FET-type microelectronic device, in particular an RFET-type microelectronic device, whose structure is compatible with any type of semiconductor material including 2D materials or other semiconductor oxide type materials, and devoid of the drawbacks of a “side contact” configuration.

For this purpose, the present invention proposes an FET microelectronic device comprising at least:
a substrate;
a semiconductor layer comprising at least one first area forming an electrical conduction channel of the FET microelectronic device;
several separate electrostatic control gates spaced apart from one another and arranged on the first area of the semiconductor layer;
a gate dielectric layer arranged between each of the electrostatic control gates and the first area of the semiconductor layer;
dielectric spacers arranged against sidewalls of each of the electrostatic control gates;
source/drain regions electrically coupled to the first areas of the semiconductor layer by second areas of the semiconductor layer, the second areas of the semiconductor layer extending between source/drain regions and the dielectric spacers;
   and wherein the second areas of the semiconductor layer are not arranged directly against the electrostatic control gate and form a continuous layer with the first area.

One embodiment provides an FET microelectronic device comprising at least:
a substrate;
a semiconductor layer comprising at least one first area forming an electrical conduction channel of the FET microelectronic device;
several separate electrostatic control gates spaced apart from one another and arranged on the first area of the semiconductor layer;
a gate dielectric layer arranged between each of the electrostatic control gates and the first area of the semiconductor layer;
dielectric spacers arranged against sidewalls of each of the electrostatic control gates;
source/drain regions electrically coupled to the first area of the semiconductor layer, the source/drain regions having or being formed by second areas of the semiconductor layer, the second areas of the semiconductor layer extending between source/drain contacts and the dielectric spacers.

Typically, the second areas of the semiconductor layer are not arranged directly against the electrostatic control gate. The second areas advantageously form a continuous layer with the first area.

The proposed microelectronic device is based on an FET-type architecture including no “side contact” type interface between the channel and the source/drain regions thanks to the second areas of the semiconductor layer providing electrical coupling between the channel formed by the first area of the semiconductor layer and the source/drain regions. These second areas of the semiconductor layer, which extend against at least part of the lateral walls, or sidewalls, of the source/drain contact, form a large contact surface with source/drain contacts, which reduces source/drain contact resistance. Thus, the electrical current circulating in the channel is not reduced because of these contact resistances, which does not reduce the performances of the device.

In addition, with the proposed architecture, the semiconductor layer can be produced just before the source/drain contacts are made or just before the metallic deposition of the source/drain contacts. Thus, the semiconductor layer whose first area is intended to form the conduction channel is not impaired by the steps involved in making the source/drain contacts. This is particularly advantageous when the semiconductor layer includes a 2D material.

Furthermore, making such a device does not require keeping silicon portions for depositing the semiconductor layer intended to form the channel, thereby eliminating the problem of a potential barrier at the interface with the material of the semiconductor layer.

The semiconductor layer may include a two-dimensional material or any other semiconductor material deposited by MOCVD (“Metal Organic Chemical Vapor Deposition”), CVD (“Chemical Vapor Deposition”) or ALD (“Atomic Layer Deposition”). In this case, the microelectronic device may be made with very small dimensions.

Advantageously, the FET microelectronic device may be such that:
each of the source/drain contacts is arranged in a cavity comprising lateral walls formed at least by the dielectric spacers and by an insulating dielectric material or by one of said dielectric spacers and an insulating spacer of a neighbouring microelectronic device;
the second areas of the semiconductor layer cover at least part of the walls of the cavities in which the source/drain contacts are arranged.

In the configuration above, the source/drain contact surfaces with the semiconductor layer are maximized thanks to the use of the surface of the walls of the cavities, and advantageously the entirety of the surface of the walls of the cavity, to form the contact between the second areas of the semiconductor layer and the source/drain contacts, which results in very low source/drain region contact resistance, and therefore a higher current flowing through the conduction channel of the device.

The microelectronic device has several separate electrostatic control gates spaced apart from one another and arranged on the first area of the active layer. In this configuration, the microelectronic device has a “Reconfigurable FET” type architecture.

The FET microelectronic device may further include at least one dielectric portion surrounded by the first area of the semiconductor layer.

Alternatively, it is possible that the first area of the semiconductor layer does not surround any dielectric portion.

Advantageously, the invention may be used to make CMOS components for 5 nm and sub-5nm technology nodes.

The invention also relates to a method for making an FET microelectronic device, comprising at least:
a) making at least one temporary material portion on a substrate, then
b) making, at least on the temporary material portion, several separate electrostatic control gates spaced apart from one another, and dielectric spacers arranged against sidewalls of each of the electrostatic control gates, then
c) etching the temporary material portion, then
d) making a semiconductor layer comprising at least one first area configured to serve as an electrical conduction channel of the FET microelectronic device, arranged beneath the electrostatic control gates and the dielectric spacers in at least one space formed by etching of the temporary material portion, and such that the semiconductor layer extends, with no discontinuity with the first area, while forming second areas covering at least part of the sidewalls of the dielectric spacers and which are not arranged directly against the electrostatic control gates, then
e) making, on the substrate, source/drain contacts electrically coupled to the first area of the semiconductor layer by the second areas of the semiconductor layer, and such that second areas of the semiconductor layer extend between the source/drain contacts and the dielectric spacers.

The method may further include, before carrying out step c), depositing an insulating dielectric material around the dielectric spacers, then etching cavities in the insulating dielectric material such that the cavities comprise at least one lateral wall formed by one of the dielectric spacers, and wherein:
step d) is carried out such that the second areas of the semiconductor layer cover at least part of the lateral walls of the cavities;
step e) is carried out such that each of the source/drain contacts is arranged in one of the cavities.

The method may further include a step of depositing a gate dielectric layer carried out:
between steps a) and b), on the temporary material portion, the electrostatic control gates being made afterwards on the gate dielectric layer, and/or
between steps c) and d), beneath the electrostatic control gates and the dielectric spacers, in at least one space formed by etching of the temporary material portion, the semiconductor layer being made afterwards by covering the gate dielectric layer.

The invention also relates to a method for making an FET microelectronic device, comprising at least:
a) making at least one temporary material portion on a substrate, then
b) making, at least on the temporary material portion, several separate temporary gates spaced apart from one another, and dielectric spacers arranged against sidewalls of each of the temporary gates, then
c) depositing an insulating dielectric material around the dielectric spacers, then
d) etching the temporary gates, and making several electrostatic control gates in place of the temporary gates, the electrostatic control gates being separate and spaced apart from one another, then
e) etching cavities in the insulating dielectric material such that the cavities comprise at least one lateral wall formed by one of the dielectric spacers, then
f) etching the temporary material portion, then
g) making a semiconductor layer comprising at least one first area configured to serve as an electrical conduction channel of the FET microelectronic device, arranged beneath the electrostatic control gates and the dielectric spacers in at least one space formed by etching of the temporary material portion, and such that the semiconductor layer extends, with no discontinuity with the first area, while forming second areas covering at least part of the sidewalls of the dielectric spacers and which are not arranged directly against the temporary gates, then
h) making, on the substrate, source/drain contacts each arranged in one of the cavities and electrically coupled to the first area of the semiconductor layer by the second areas of the semiconductor layer, and such that second areas of the semiconductor layer extend between the source/drain contacts and the dielectric spacers.

The method may further include a step of depositing a gate dielectric layer carried out:
during step e), on the first area of the semiconductor layer, the electrostatic control gates being made afterwards on the gate dielectric layer, and/or
between steps c) and d), beneath the temporary gates and the dielectric spacers, in at least one space formed by etching of the temporary material portion, the semiconductor layer being made afterwards by covering the gate dielectric layer.

Throughout the document, the terms “on” and “beneath” are used without distinction as to the orientation in space of the element to which the term refers. For example, in the feature “on a face of the first substrate”, this face of the first substrate is not necessarily oriented upwards but may correspond to a face oriented in any direction. Furthermore, the arrangement of a first element on a second element should be understood as possibly corresponding to the arrangement of the first element directly against the second element, without any intermediate element between the first and second elements, or as possibly corresponding to the arrangement of the first element on the second element with one or more intermediate element(s) arranged between the first and second elements.

Throughout the document, the term “layer” may refer to a single layer or to a stack of several layers.

Throughout the document, the expression “electrically couple” is used to refer to an electrical connection which may be direct or indirect (i.e. established via one or more intermediate electrical elements).

### BRIEF DESCRIPTION OF THE DRAWINGS

The present invention will be better understood upon reading the description of non-limiting exemplary embodiments given purely by way of illustration, with reference to the appended drawings, in which:

FIG. 1 to FIG. 5 schematically show the steps of a method for making the microelectronic device, object of the present invention, according to one particular embodiment;

FIG. 6 schematically shows a microelectronic device, object of the present invention, according to an alternative embodiment.

Identical, similar or equivalent parts in the different figures described hereinafter bear the same reference numerals so as to make it easier to switch from one figure to another. The various parts shown in the figures are not necessarily represented on a uniform scale, to make the figures easier to read.

The various possibilities (alternatives and embodiments) should be understood as not being mutually exclusive and may be combined.

### DETAILED DISCLOSURE OF PARTICULAR EMBODIMENTS

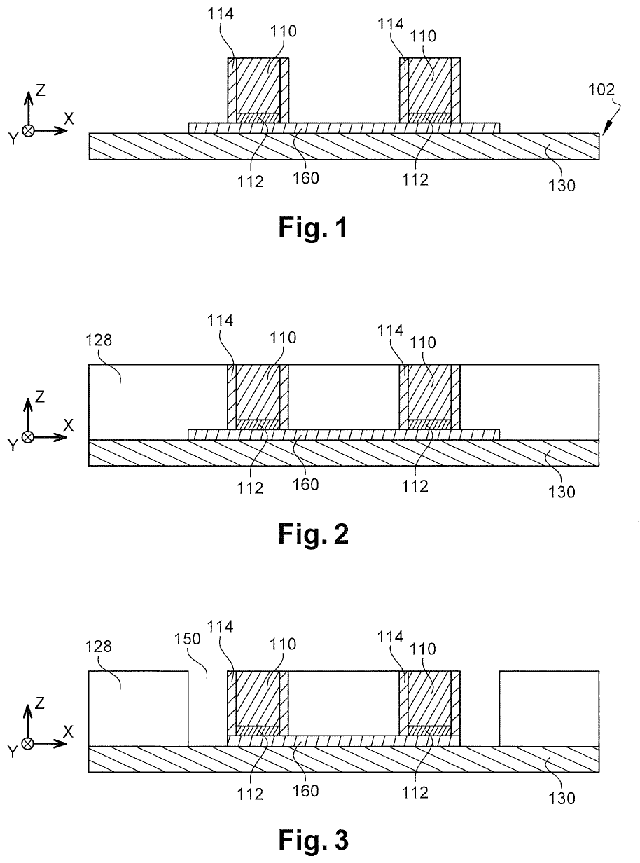

A method for making a “Reconfigurable FET” type device 100 according to one particular embodiment is described below with reference to FIGS. 1 to 5.

Etching of a semiconductor layer, corresponding for example to the surface layer of an SOI-type substrate 102, is carried out so as to form, on the substrate 102 (on the buried dielectric layer 130 in the example described), a temporary material portion 160. Alternatively, the substrate 102 can be a bulk substrate.

A dielectric layer 112 and several electrostatic control gates 110 are produced on the temporary portion 160 and spaced apart from one another (see FIG. 1). In the example described here, the device 100 has two gates: a control gate and a polarity gate. The gates 110 produced are separate and spaced apart from one another.

For example, the layer 112 includes a high-K dielectric material (with a high dielectric permittivity) such as HfO2. Alternatively, this layer 112 may include SiO₂ or Al₂O₃ or any other suitable material or combination of materials.

For example, the control gates 110 are made by depositing one or more conductive material(s) on the layer 112, for example a first deposition of a thin TiN layer (a thickness for example equal to 3 nm) on which a tungsten layer with a thickness for example equal to 200 nm is stacked. Alternatively, the gates 110 may include one or more material(s) other than TiN or W, like for example doped polysilicon or any other metal (Mo, etc.). Dielectric spacers 114 are produced against the sidewalls of the gates 110. For example, a material suitable for making the dielectric spacers 114 corresponds to SIN, SiCO or SiBCN. The thickness of the layer deposited to make the dielectric spacers 114 is for example comprised between 5 nm and 15 nm.

After the spacers 114 have been formed, an insulating dielectric material 128, for example SiO₂, is then deposited and then planarized with a stop on the hard mask present on the gates 110 (not shown in the figures). The insulating dielectric material 128 is deposited with a large thickness, and then a planarisation is implemented until reaching the hard mask. The hard mask is then removed for example by wet etching, for example using a diluted H₃PO₄ solution used at a temperature of 110 °C.

The structure obtained at this stage of the method is shown in FIG. 2.

Cavities 150 are then etched into the insulating dielectric material 128 (see FIG. 3). The cavities 150 comprise lateral walls formed by the dielectric spacers 114 and remaining portions of the insulating dielectric material 128. These cavities 150 form spaces for making the source and drain regions of the device 100. The parts of the temporary portion 160 not covered by the gates 110, the gate dielectric layer 112 and the dielectric spacers 114 and located at the bottom of the cavities are etched.

The remaining part of the temporary portion 160 covered by the gates 110, the gate dielectric layer 112 and the dielectric spacers 114 is etched, then a semiconductor layer 120 is deposited such that a first area 122 of the semiconductor layer 120 forms a semiconductor material portion arranged on the substrate 102 and such that the gates 110 and the gate dielectric layer 112 are arranged on this first area 122 of the semiconductor layer 120. In addition, in the example shown in FIG. 4, a dielectric layer 152 is deposited before the semiconductor layer 120.

Second areas 124 of the semiconductor layer 120 cover the walls of the cavities 150. These second areas 124 form a continuous layer 120 with the first area 122. These second areas 124 belong to the source and drain regions or form the source and drain regions.

Advantageously, the semiconductor layer 120 includes at least one 2D semiconductor material, for example a transition-metal dichalcogenide such as MoS₂, or WSe₂, or WS₂, or MoTe₂. It is also possible that the material of the semiconductor layer 120 corresponds to IGZO, In₂O₃, IWO, ITO, or an amorphous semiconductor oxide, or any other suitable semiconductor material.

Source region contacts 116 and drain region contacts 118, also known as source contact 116 and drain contact 118 respectively, are made in the cavities 150 by depositing, in the example described, one or more metal material(s) in the cavities 150. Before this or these metal(s) is/are deposited, it is possible to deposit a graphene layer in the cavities 150, this or these metal(s) then being deposited on the graphene layer. These source 116 and drain 118 contacts shown in FIG. 5, are electrically coupled to the first area 122 of the semiconductor layer 120 via the second areas 124 of the semiconductor layer 120 which extend between the source 116/drain 118 contacts and the dielectric spacers 114 as well as against the other walls of the source 116/drain 118 contacts located in the cavities 150. The material of these regions deposited outside the cavities 150 is eliminated by implementation of a planarisation with stoppage at the insulating dielectric material 128. Advantageously, the source 116 and drain 118 contacts respectively include at least one metal material such as gold, palladium, TIN, W, Ni, etc. According to one exemplary embodiment, each of the source 116/drain 118 contacts includes a TiN layer over which a tungsten portion is formed. Different metals may be used to form the contacts 116, 118 in order to favour low contact resistance, such as: S, Bi, Sn, Pd, Ru, Cu, Ni, Ti, TiN, W, Au, etc. These materials may also be modified later on (to improve their properties), for example through a doping step.

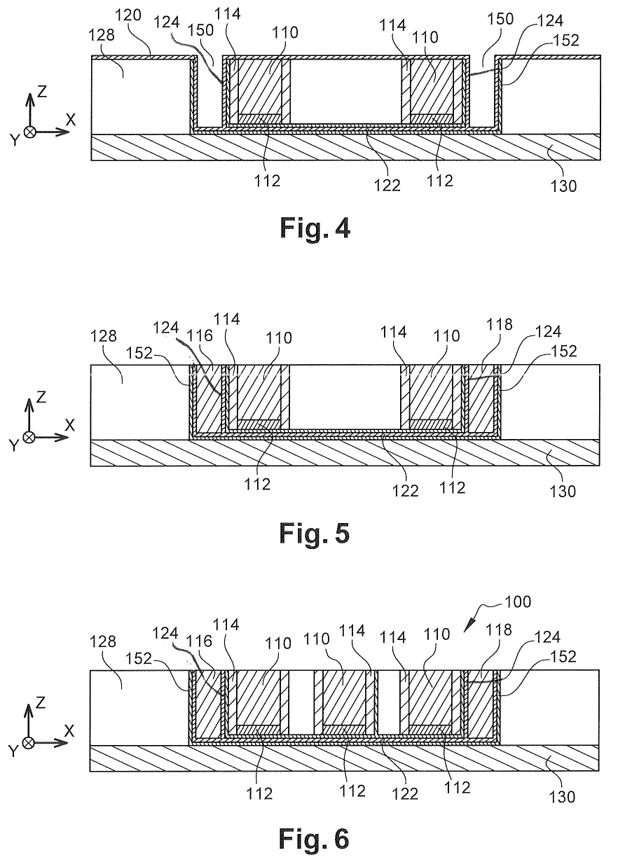

In the exemplary embodiment described above, the semiconductor layer 120 is such that the space previously occupied by the temporary portion 160 is completely filled by the material of the semiconductor layer 120. Alternatively, it is possible that the semiconductor layer 120 does not completely fill the space previously occupied by the temporary portion 160. In this case, after the deposition of the semiconductor layer 120, the remaining space(s) is/are filled by dielectric material so as to form a dielectric portion surrounded by the first area 122 of the semiconductor layer 120. To form this dielectric portion, one ore more dielectric layer(s), comprising for example Al₂O₃ (or HfO₂) and/or SiO₂ (or a low-k dielectric, or with a low dielectric permittivity), are deposited and then isotropically etched so as to keep only the portion located in the remaining space. Alternatively, the device 100 can comprise a different number of gates. Thus, in the example shown in FIG. 6, the device 100 has three gates: two control gates and one polarity gate.

In the different examples described above, the second areas 124 of the semiconductor layer 120 cover all of the sidewalls and the bottom walls of the source 116 and drain 118 contacts so as to completely cover these contacts, except on an upper end portion opposite the bottom walls. This end portion is preferably flush with a mouth of the cavities 150. In general, it is possible that the second areas 124 of the semiconductor layer 120 extend between the source 116 and drain 118 contacts and the dielectric spacers 114 and/or against walls of the source and drain contacts different from those arranged against the dielectric spacers 114. Furthermore, the walls of the source 116 and drain 118 contacts may be covered only partially by the second areas 124 of the semiconductor layer 120.

In the first and second exemplary embodiments described above, the gate dielectric layer 112 and the electrostatic control gates 110 are made on the temporary material portion 160 before the insulating dielectric material 128 is deposited and planarized (a so-called “gate first” approach).

Alternatively, using a “gate last” approach, it is possible to produce, in place of the gate dielectric layer 112 and the electrostatic control gates 110 and before the insulating dielectric material 128 is deposited and planarized, several temporary gates arranged on temporary dielectric portions which are themselves arranged on the temporary material portion 160. The temporary dielectric portions comprise, for example SiO₂, and the temporary gates have, for example, polysilicon. These temporary elements are produced by depositing the desired layers of material, planarizing the polysilicon layer and etching these layers according to the desired geometry for these temporary gates (geometry similar to that of the final gates produced later). The dielectric spacers 114 are then produced on the sidewalls of the temporary gates. After the insulating dielectric material 128 has been deposited and planarized, the temporary gates and the temporary dielectric portions are removed by etching, then the gate dielectric layer 112 and the electrostatic control gates 110 are made in the spaces formed by etching of the temporary gates and temporary dielectric portions. The device 100 is then completed in a similar way to the method described above by carrying out the steps described with reference to FIGS. 3 to 5.

In the exemplary embodiments described above, the gate dielectric layer 112 is made just before making the electrostatic control gates 110, whether temporary gates have been used or not. Alternatively, it is possible that the electrostatic control gates 110 are made without having made the gate dielectric layer 112 beforehand. In this case, the gate dielectric layer 112 may be deposited just before depositing the semiconductor layer 120, at least against the walls of the space obtained by etching the temporary material portion 160. In this case, the layer 112 covers the different walls on which the material of the semiconductor layer 120 is intended to be deposited, thereby homogenizing the surfaces, and therefore the interfaces, against which the semiconductor layer 120 is then deposited.

According to another alternative, it is possible that the layer 112 is deposited in two different steps: first of all just before making the gates 110 as described above with reference to FIG. 1, then in the spaces formed by etching of the portions 160 and in the cavities 150, just before deposition of the semiconductor layer 120. In this case, the parts of the layer 112 located directly above the gate 110 are thicker than the other parts of the layer 112 because these parts accumulate the material thicknesses deposited during the two deposition steps.

1. An FET microelectronic device, comprising at least:
a substrate;
a semiconductor layer comprising a first area forming an electrical conduction channel of the FET microelectronic device;
a plurality of separate electrostatic control gates spaced apart from one another and arranged on the first area of the semiconductor layer;
a gate dielectric layer arranged between each of the electrostatic control gates and the first area of the semiconductor layer;
dielectric spacers arranged against sidewalls of each of the electrostatic control gates; and
source/drain regions electrically coupled to the first area of the semiconductor layer, the source/drain regions being formed by second areas of the semiconductor layer, the second areas of the semiconductor layer extending between source/drain contacts and the dielectric spacers wherein the second areas of the semiconductor layer are not arranged directly against the electrostatic control gate and form a continuous layer with the first area.

2. The FET microelectronic device according to claim 1, wherein the semiconductor layer includes a two-dimensional material.

3. The FET microelectronic device according to one of claim 1, wherein:
each of the source/drain contacts is arranged in a cavity comprising lateral walls formed at least by the dielectric spacers and by an insulating dielectric material or by one of said dielectric spacers and an insulating spacer of a neighbouring microelectronic device; and
the second areas of the semiconductor layer cover at least a part of the walls of the cavities in which the source/drain region contacts are arranged.

4. The FET microelectronic device according to claim 1, further comprising at least one dielectric portion surrounded by the first area of the semiconductor layer.

5. The FET microelectronic device according to claim 1, wherein the second areas of the semiconductor layer completely cover the sidewalls and a bottom wall of each of the source and drain contacts.

6. A method for making an FET microelectronic device, the method comprising:
(a) making a temporary material portion on a substrate,
(b) making, at least on the temporary material portion, a plurality of separate electrostatic control gates spaced apart from one another, and dielectric spacers arranged against sidewalls of each of the electrostatic control gates,
(c) etching the temporary material portion,
(d) making a semiconductor layer comprising a first area configured to serve as an electrical conduction channel of the FET microelectronic device, arranged beneath the electrostatic control gates and the dielectric spacers in at least one space formed by etching of the temporary material portion, wherein the semiconductor layer extends, with no discontinuity with the first area, while forming second areas covering at least part of the sidewalls of the dielectric spacers and which are not arranged directly against the electrostatic control gates, the second areas forming source/drain regions, and
(e) making, on the substrate, source and drain contacts electrically coupled to the first area of the semiconductor layer by the second areas of the semiconductor layer, wherein second areas of the semiconductor layer extend between the source/drain contacts and the dielectric spacers,
wherein the method further comprises making a gate dielectric layer arranged between each of the electrostatic control gates and the first area of the semiconductor layer.

7. The method according to claim 6, further comprising, before performing step (c), depositing an insulating dielectric material around the dielectric spacers, then etching cavities in the insulating dielectric material such that the cavities comprise at least one lateral wall formed by one of the dielectric spacers, wherein:
step (d) is performed such that the second areas of the semiconductor layer cover at least part of the lateral walls of the cavities; and
step (e) is performed such that each of the source/drain contacts is arranged in one of the cavities.

8. The method according to claim 6, further comprising depositing the gate dielectric layer, which is performed;
between steps (a) and (b), on the temporary material portion, the electrostatic control gates being made afterwards on the gate dielectric layer, and/or
between steps (c) and (d), beneath the electrostatic control gates and the dielectric spacers, in at least one space formed by etching of the temporary material portion, the semiconductor layer being made afterwards by covering the gate dielectric layer.

9. A method for making an FET microelectronic device, the method comprising:
(a) making a temporary material portion on a substrate,
(b) making, at least on the temporary material portion, several separate temporary gates spaced apart from one another, and dielectric spacers arranged against sidewalls of each of the temporary gates,
(c) depositing an insulating dielectric material around the dielectric spacers,
(d) etching the temporary gates, and making several electrostatic control gates in place of the temporary gates, the electrostatic control gates being separate and spaced apart from one another
(e) etching cavities in the insulating dielectric material such that the cavities comprise at least one lateral wall formed by one of the dielectric spacers,
(f) etching the temporary material portion,
(g) making a semiconductor layer comprising a first area configured to serve as an electrical conduction channel of the FET microelectronic device, arranged beneath the electrostatic control gates and the dielectric spacers in at least one space formed by etching of the temporary material portion, wherein the semiconductor layer extends, with no discontinuity with the first area, while forming second areas covering at least part of the sidewalls of the dielectric spacers and which are not arranged directly against the temporary gates, the second areas forming source/drain regions, and
(h) making, on the substrate, source and drain contacts each arranged in one of the cavities and electrically coupled to the first area of the semiconductor layer by the second areas of the semiconductor layer, wherein second areas of the semiconductor layer extend between the source/drain contacts and the dielectric spacers,
wherein the method further comprises making a gate dielectric layer arranged between each of the electrostatic control gates and the first area of the semiconductor layer.

10. The method according to claim 9, further comprising depositing the gate dielectric layer, which is performed:
during step (d), in the spaces formed by etching of the temporary gates, the electrostatic control gates being made afterwards on the gate dielectric layer, and/or
between steps (c) and (d), beneath the temporary gates and the dielectric spacers, in at least one space formed by etching of the temporary material portion, the semiconductor layer being made afterwards by covering the gate dielectric layer.
